(19) United States
(12) Patent Application Publication
(10) Pub. No.: US 2009/0250093 A1
(43) Pub. Date: Oct. 8, 2009

(54) Enhanced concentrator PV pannel

(76) Inventor: Zupei Chen, Cupertino, CA (US)

Correspondence Address: DAHYEE LAW GROUP, 5776 Stoneridge Mall RD, SUITE288, Pleasanton, CA, 94588, US

(21) Appl. No.: 12/231,046

(22) Filed: Aug. 29, 2008

Related U.S. Application Data
(60) Provisional application No. 61/123,437, filed on Apr. 8, 2008.

(51) Int. Cl. H01L 31/042

(52) U.S. Cl. 136/246

(57) ABSTRACT

The invention teaches a family of flat concentrator PV panels wherein an array of enhanced light beam splitters coupling with a plurality of optical grooves efficiently collects light and transmits collected light substantially to the active surface(s) of an array of size-reduced PV cells with low aspect ratio.

### REFERENCE TO RELATED APPLICATION

The present application claims priority to the provisional Appl. Ser. No. 61/123,437 filed on Apr. 8, 2008, the entire content of which is hereby incorporated by reference.

### FIELD OF THE INVENTION

The present invention relates in general to photovoltaic technology. More particularly, the invention relates to a flat concentrator PV panel in which an array of enhanced light beam splitters coupling with a plurality of optical grooves efficiently collects light and transmits collected light substantially to the active areas of an array of size-reduced photovoltaic cells with a low aspect ratio.

### BACKGROUND OF THE INVENTION

Flat plate Photovoltaic (PV) panel is a system that produces electricity by having sunlight directly strike PV cells made of expensive semiconductor material.

To reduce the cost, concentrator PV panel which requires less PV cell consumption is being highlighted in today's market. Concentrator PV technologies use relatively inexpensive optics such as mirrors or lenses to concentrate or focus light from a relatively broad collection area onto a much smaller area of active semiconductor PV material. Conventional Concentrator PV systems must be pointed directly at the sun because they work by focusing sunlight onto a targeted area, and hence they require trackers which follow the sun's trajectory throughout the day. Since concentrator PV systems require less semiconductor material to capture a given amount of sunlight, it is still cost-effective to use more expensive and higher efficiency cells to increase the electricity generated from a given collection area. Indeed, concentrator PV approaches offer an effective, practical way to keep solar cell conversion efficiencies high while keeping semiconductor material costs down.

Taking consideration that the incident angel of the sunlight various over one year, North to South is approximately 47° and East to West is approximately 180°, it is calculated that a linear concentrator PV panel with one dimensional concentration may be best for terrestrial solar generation system application.

Over the past twenty years, there have been various solutions in the field of concentrator PV panel with PV cells arranged in rows that look like a strip array of solar cells. In this type of PV panels, such as the PV panel illustrated in FIG. 1, which includes a cover glass 101, a middle layer 103 and a back layer 104. Some sunlight, such as 106, directly impinges on an array of PV cell strips 102 which is embedded in the middle layer 103. Some other sunlight, such as 107a, impinges on an array of reflective beam splitters, such as 105, coupled in between two neighboring solar cell strips 102. The reflected light 107b, 107c from the reflective beam splitter 105 is then totally internally reflected (107b to 107d, and 107c to 107e) by the front surface 101a of the cover plate 101 to the nearest PV cell strips 102. The magnification, i.e., the ratio of the pitch b1 of the PV cell array and the width a1 of the PV cell strip 102, is about 2 usually.

In U.S. Pat. No. 5,877,874, Glenn A. Rosenberg disclosed a holographic planar concentrator (HPC) as the beam splitter for collecting and concentrating optical radiation. The holographic planar concentrator comprises a planar highly transparent plate and at least one multiplexed holographic optical film mounted on a surface thereof. The multiplexed holographic optical film has recorded therein a plurality of diffractive structures having one or more regions which are angularly and spectrally multiplexed. Two or more of the regions may be configured to provide spatial multiplexing. The HPC is fabricated by: (a) recording the plurality of diffractive structures in the multiplexed holographic optical film employing angular, spectral, and, optionally, spatial multiplexing techniques; and (b) mounting the multiplexed holographic optical film on one surface of the highly transparent plate. The recording of the plurality of diffractive structures is tailored to the intended orientation of the holographic planar concentrator to solar energy. The HPC is mounted in the intended orientation for collecting solar energy and at least one solar energy-collecting device is mounted along at least one edge of the holographic planar concentrator.

In U.S. Pat. No. 7,238,878, Ronald C. Gonsiorawski disclosed a PV panel with V-shaped grooves as a beam splitter running in at least two directions and coated with a light reflecting medium so as to provide light-reflecting facets that are aligned with the spaces between adjacent cells and oriented so as to reflect light falling in those spaces back toward the transparent front cover for further internal reflection onto the solar cells, whereby substantially all of the reflected light will be internally reflected from the cover sheet back to the PV cells, thereby increasing the current output of the module.

In U.S. Pat. No. 7,164,839, Eldon H. Nyhart, Jr., et al disclosed a radiation collector configured to collect incident radiation. The radiation collector includes a radiation directing component as a beam splitter configured to redirect the incident radiation, a buffer component configured to receive the radiation redirected by the radiation directing component, and a propagation component configured to receive the radiation from the buffer component and to propagate the radiation towards a first end of the propagation component.

Those approaches fail to provide wide angle of view with sufficiently high concentration ratio and thus are much limited. What is desired is a flat concentrator PV panel in which an array of enhanced light beam splitters coupling with a plurality of optical grooves efficiently collects light and transmits collected light substantially to the active areas of an array of size-reduced photovoltaic cells with a low aspect ratio.

### SUMMARY OF THE INVENTION

The present invention teaches a concentrator PV panel with a small view angle not less than 40 degree and a large view angle equal to 180 degree, perpendicular to each other that satisfies a fixed ground solar generation system application criteria. The PV panel includes rows of PV cell or a linear array of PV cells connecting in series and/or in parallel, alternating with rows of optical reflective beam splitters. The PV cell rows and beam splitter rows completely covers the light-incident surface of the PV panel. The PV cell array is sandwiched in between a transparent cover plate and a back plate using an adhesive. The back plate is insulating and humidity-proof. To reduce the optical length and increase concentration ratio, rows of grooves with flat or curved sidewalls are formed on the front surface of the transparent cover plate, each of which being parallel to and above of a PV cell row. A humidity protected mirror is attached on the back surface of the back plate.

In another aspect, the PV cell array is sandwiched in between a transparent cover plate and a transmitting plate using a transparent and insulating adhesive. The PV cell array formed by a plurality of bifacial PV cell rows that are placed in parallel to each other separated by a space and are electrically connected in series or in parallel. An array of grooves for optical length reduction and an array of grooves for beam splitting enhancement are formed on the back surface of the transmitting plate. The beam splitting enhancement grooves are arranged alternate with the optical length reduction grooves. Each beam splitting enhancement groove and the adjacent optical length reduction groove are connected by a cylindrical surface. A humidity protected mirror is attached on the back surface of the transmitting plate.

In one preferred embodiment, the concentrator PV panel includes (a) a light transparent cover plate with an anti-reflection flat front surface and a back surface; (b) a transmitting plate with a front surface and a grooved back surface; (c) a PV cell array which is sandwiched in between the light transparent cover plate and the transmitting plate using a transparent and insulating adhesive; (d) a reflector attached onto the back surface of the transmitting plate.

In another implementation, the grooved back surface in the above described preferred embodiment has an array of optical length reduction grooves, each of which having a pair of bent symmetrical sidewalls. Every two optical length reduction grooves are connected to each other through a flat surface. The symmetrical sidewalls have flat or curved surfaces. For the curved surface, the cross sectional view of the curved surface can be parabolic, elliptical, spherical, or a step curve.

Yet in another implementation, the grooved back surface in the above described embodiment has a plurality of optical length reduction grooves alternating with a plurality of beam splitting enhancement grooves on the back surface of the transmitting plate. Every two beam splitting enhancement grooves are connected to each other through either a flat surface or a circular surface having a diameter substantially equal to the thickness of the light transmitting plate. Each beam splitting enhancement groove has a pair of symmetrical flat sidewalls or a pair of symmetrical curved sidewalls, with a groove angle larger than 90 degree and a depth in the range between 0 and the thickness of the transmitting plate.

In another preferred embodiment, the concentrator PV panel includes (a) a light transparent cover plate with a grooved front surface and a back surface; (b) a transmitting plate with a front surface and a grooved back surface; (c) a PV cell array which is sandwiched in between the light transparent cover plate and the transmitting plate using a transparent adhesive; and (d) a reflector attached onto the back surface of the transmitting plate. The grooved front surface has an array of total internal reflection (TIR) grooves, each of which having a pair of flat or curved sidewalls. The cross sectional view of the curved sidewall can be parabolic, elliptical, spherical, or a step curve. Every two TIR grooves are connected to each other through a flat surface.

In an alternative implementation, the grooved back surface in the above described preferred embodiment has a plurality of optical length reduction grooves alternating with a plurality of beam splitting enhancement grooves. Every two nearest adjacent beam splitting enhancement grooves are connected to each other through a pair of circular curved surfaces having a diameter equal to the thickness of the light transmitting plate. Each of the optical length reduction grooves has a pair of symmetrical flat or curved sidewalls connecting each other through a flat surface with groove angle larger than 90 degree and depth in the range from 0 to the thickness of the transmitting plate.

Yet in another alternative implementation, each of the beam splitting enhancement grooves has a pair of symmetrical planar sidewalls spaced by a planar beam splitter. The angle between the symmetrical sidewalls is large than 90 degree. The planar beam splitter can be any of: a mirror coated V-shape groove, a diffuser, a hologram grating, a Bragg Grating, and an array of micro V-shape grooves.

### BRIEF DESCRIPTION OF DRAWINGS

For a more succinct understanding of the nature and objects of the present invention, reference should be directed to the following detailed description taken in connection with the accompanying drawings in which:

FIG. 1 is a schematic fragmentary diagram illustrating a sectional view of a flat plate PV panel according to the prior arts;

FIG. 2 is a schematic fragmentary diagram illustrating a sectional view of a flat concentration plate PV panel according to one preferred embodiment of the present invention;

FIG. 3 is a schematic fragmentary diagram illustrating a sectional view of a flat concentration plate PV panel according to another preferred embodiment of the present invention;

FIG. 4 is a schematic fragmentary diagram illustrating a sectional view of a flat concentration plate PV panel according to another preferred embodiment of the present invention;

FIG. 5 is a schematic fragmentary diagram illustrating a sectional view of a flat plate concentration PV panel according to another preferred embodiment of the present invention;

FIG. 6 is a schematic fragmentary diagram illustrating a sectional view of a flat plate concentration PV panel according to another preferred embodiment of the present invention; and

FIG. 7 is a schematic diagram illustrating a cross sectional view of a beam splitter which is used in the embodiments illustrated in FIGS. 2-6.

### DETAILED DESCRIPTION OF THE INVENTION

While the present invention may be embodied in many different forms, designs or configurations, for the purpose of promoting an understanding of the principles of the invention, reference will be made to the embodiments illustrated in the drawings and specific language will be used to describe the same. It will nevertheless be understood that no limitation of the scope of the invention is thereby intended. Any alterations and further implementations of the principles of the invention as described herein are contemplated as would normally occur to one skilled in the art to which the invention relates.

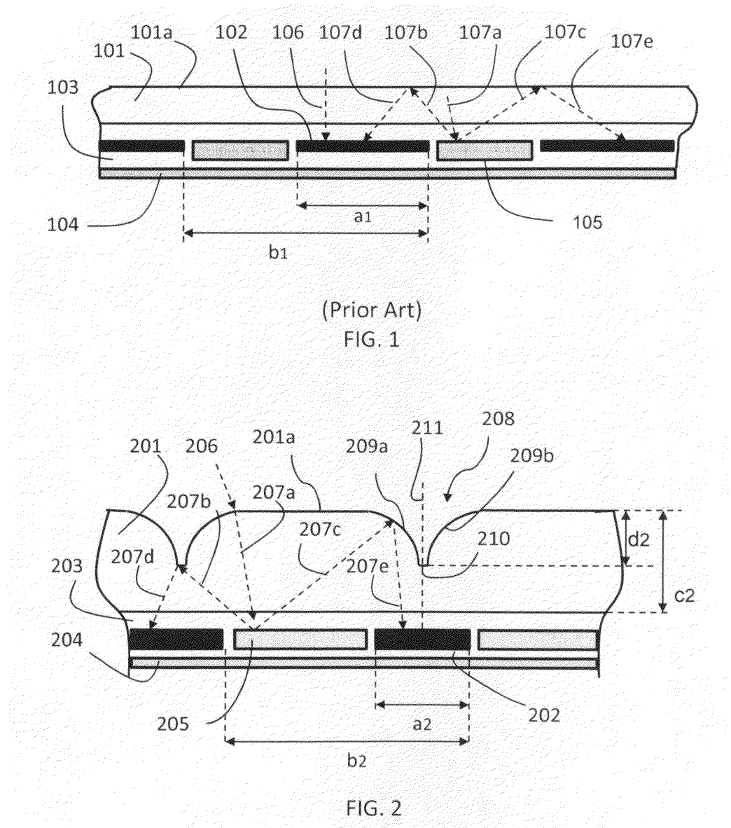

Referring to FIG. 1, which is a schematic fragmentary diagram illustrating a sectional view of a flat plate PV panel according to the prior art, the PV panel includes a cover glass 101, a water proof back plate 104, and an array of PV cells, such as 102, which is sandwiched between the cover glass 101 and the water proof back plate 104 by a transparent and insulative adhesive layer 103, and an array of planar reflective beam splitters such as 105. The PV cell rows 102 are spaced evenly. Each reflective beam splitter strip 105 is locating between two nearest adjacent PV cell rows 102. Except partial of light 106 impinging to PV cells 102 directly, other light is refracted at front surface 101a of the cover plate 101 and transmits in the cover plate into the refraction light 107a. The reflective beam splitter 105 splits the refraction light 107a into two beams 107b and 107c which are reflected onto the nearest PV cells 102 through TIR of the front surface 101a of the cover plate 101. The reflective beam splitter 105 can be a diffuser, a grating, or a micro V groove array. Due to the function of the reflective beam splitter 105, the pitch b1 of PV cell array can be larger than the width a1 of the PV cell 102. The concentration ratio is dependent on the ratio of b2/a2. To reduce the loss of reflective light, the front surface 101a contains an anti-reflection coating or includes an anti-reflection pattern structure.

The preferred embodiments of the present invention illustrated below have substantially improved the prior arts.

FIG. 2 is a schematic fragmentary diagram illustrating a cross sectional view of a flat plate concentrator PV panel according to one preferred embodiment of the present invention. The concentrator PV panel includes a cover plate 201, which is made of a light transparent optical medium, such as optical glass, having an array of grooves such as 208 on the front surface, an array of PV cell strips such as 202 which may be crystalline silicon PV cell, a back plate 204, and an array of reflective beam splitters such as 205. The PV cell array and the reflective beam splitter array are sandwiched between the cover plate 201 and the water proof back plate 204 by a transparent electrical insulative adhesive 203. The cover plate 201 has an anti-reflection layer on the front outer surface. In a typical implementation, the anti-reflection layer may be a dielectric coating or a micro V groove array with pitch size approximately 0.2˜2 mm. The micro V groove's inner angle between its two sidewalls is less than 90 degree. The micro V groove array and the TIR groove array are perpendicular to each other.

The TIR grooves such as 208, the rows of PV cells such as 202, and the strips of reflective beam splitters such as 205 are parallel to each other. Each TIR groove of the TIR groove array is designed in such a manner that it is located directly above the relative PV cell row of the PV cell array.

Each TIR groove 208 has two sidewalls 209a and 209b which are symmetrical to the central line 211. The bottom 210 of the TIR groove 208 can be flat or curved. The depth d2 of the TIR groove 208 and the thickness c2 of the cover plate 201 are determined for the most effective TIR purpose in accordance with the geometrical properties of the sidewalls 209a and 209b. Typically, d2 is in a range of 0.5-10 mm. The longitudinal axis of the TIR groove 208 is parallel to the longitudinal axis of the PV cell row 202, but the cross section of the TIR groove 208 at a right angle to its longitudinal direction and the cross section of the nearest PV cell row 202 at a right angle to its longitudinal direction share a same central line 211.

The reflective beam splitters 205 can be optical diffusers, a gratings, or micro V grooves. As an example, the incident light 206 is refracted on the front surface 201a and transmitted through the cover plate 201 as light 207a. The light 207a impinging on the reflective beam splitter 205 is then split into two light beams 207b and 207c. The lights 207b and 207c are totally reflected on the inner surface of the front surface 201a of the cover plate 201. The reflected lights 207d and 207e ultimately substantially travel backwards to two nearest PV cells 202.

Due to the innovative design as illustrated in FIG. 2, relatively less PV cells are required for a same size PV panel. For example, in a same size implementation, the pitch b2 for the PV cell rows in FIG. 2 is the same as the pitch b1 of the PV cell rows in FIG. 1, but the required width a2 for the PV cell rows in FIG. 2 is much less than the required width a1 for the PV cell rows in the PV panel illustrated in FIG. 1. Thus, the magnification is higher and the light energy is used more effectively in the present embodiment of the invention.

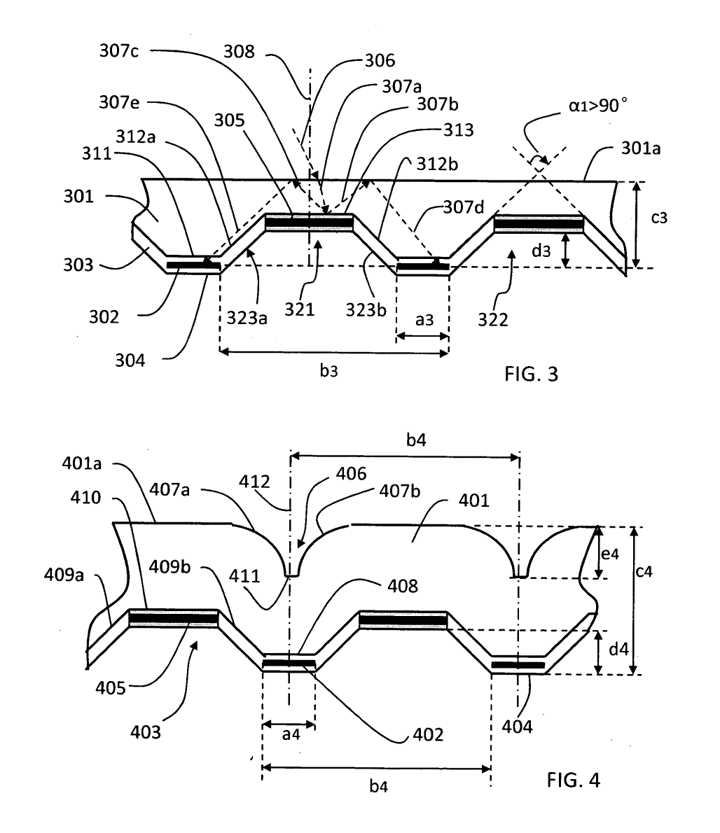

FIG. 3 is a schematic fragmentary diagram illustrating a flat plate concentrator PV panel according to another preferred embodiment of the present invention. The concentrator PV panel includes a cover plate 301 made of a light transparent optical medium such as optical glass. The cover plate 301 has a flat front anti-reflection surface 301a and a grooved back surface 311. A number of trapezoidal grooves, such as 321 and 322, are evenly spaced in parallel and are located on the back surface 311 of the cover plate 301. Here, “front surface” refers to the side of the concentrator PV panel facing the light source such as sun, and “back surface” refers to the side of the PV panel backing the light source. The back surface is usually mounted to a support structure such as a frame.

Various strips of reflective beam splitters, such as 305, are evenly spaced in parallel with a spacing b3 which is in the range between 1 mm to 100 mm. Each trapezoidal groove 321 has a flat top surface 313 and a pair of sidewalls 312a and 312b which are symmetrical to a central line 308 at a right angle to a longitudinal direction of the trapezoidal groove and has a groove angle α1 between the symmetrical sidewalls larger than 90 degrees and a depth d3 in the range between 0 and the thickness c3 of the cover plate 301. Typically, angle α1 is in a range of 90-160 degrees. The groove depth d3 and the cover plate thickness c3 are determined for the most effective TIR purpose in accordance with the geometrical properties of the sidewalls 323a and 323b. Typically, d3 is in a range of 0.5-50 mm.

In a typical implementation, every trapezoidal groove 321 is connected to two nearest adjacent trapezoidal grooves through a PV cell row such as 302. The PV cell rows are evenly spaced in parallel and are coupled in the layer 303 and in the areas near the bottom plane 304 between two adjacent trapezoidal grooves. The PV cell rows 302, the trapezoidal grooves 321 and the reflective beam splitter strips 313 are in parallel to each other.

Here, “trapezoidal groove” refers to a 3-dimensional structure in which any cross section view at a right angle to its longitudinal axis is a trapezoid with two parallel sides of different length and a pair of symmetrical unparallel sides of identical length. Its top surface refers to the plane where the trapezoid's narrow side resides. Its bottom plane refers to the plane where the trapezoid's wide side resides.

The reflective beam splitter 305 can be an optical diffuser, a grating, or an array of micro V shape grooves. As an example, the refractive light 307a of light 306 impinges on the reflective beam splitter 305, and is split into reflective lights 307b and 307c, which are further reflected upwardly to the inner surface of the front surface 301a. Upon TIR, reflective lights 307d and 307e travel ultimately substantially to the active area of the PV cell 302. The geometry of symmetrical sidewalls 323a and 323b of the trapezoidal groove 321 is such that the light impinging on the sidewall 323a or 323b is substantially reflected to the front surface 301a and ultimately substantially backwards toward the surface of the PV cell 302. Because of this geometrical design, relatively less PV cells are required for a PV panel.

Note that the reflective beam splitters 305 and the concentrator PV cell rows 302 are located on different planes. By placing the reflective beam splitter 305 on the top plane 313 of the trapezoidal groove 321 for beam splitting enhancement, low aspect ratio As=c3/b3 can be achieved in 1.5-4 at very low cost.

Now referring to FIG. 4 which is a schematic fragmentary diagram illustrating a sectional view of a flat plate concentrator PV panel according to another preferred embodiment of the present invention. This embodiment is a combination of the embodiment illustrated in FIG. 2 and the embodiment illustrated in FIG. 3. The concentrator PV panel includes a cover plate 401 made of a light transparent optical medium, such as optical glass, having an array of V shape TIR grooves such as 406 in the front surface 401a, an array of PV cell rows such as 402 in the bottom surface areas 408 connecting the neighboring trapezoidal grooves 403, an array of reflection beam splitters such as 405 in the top surface area 410 of the trapezoidal groove 403, and a back cover mirror 404. Here, “front surface” refers the surface of the cover plate facing the source of the incident light. The cover plate 401 in FIG. 4 is similar to the cover plate 201 in FIG. 2. The back cover mirror 404 can be a single layer mirror or a multi-layer mirror with identical optical properties. The two-layer description herein is for illustration only. Single layer or multi-layer implementations depend on cost effectiveness for manufacturing.

Each TIR groove, such as 406, of the TIR groove array is located directly above the relative PV cell row such as 402. With a pitch range b4 which is approximately 5 mm-100 mm, each TIR groove in the front surface has two sidewalls 407a and 407b symmetrical to the central line 412, and a bottom surface 411 which is parallel to the relative PV cell row 402. The symmetrical sidewalls can be either flat or curved surfaces. For a pair of symmetrical curved surfaces, the cross sectional view of a surface can be parabolic, elliptical, spherical, or step curve. The geometrical properties of the sidewalls are designed according to such a calculation that they, with TIR properties, redirect the reflected light from each reflective beam splitter such as 405 of the reflective beam splitter array, substantially to the active areas of two nearest adjacent PV cell rows such as 402. In other words, the sidewalls 407a and 407b of the TIR groove 406 totally internally reflect substantially all the light from the reflective beam splitter 405 to the PV cell rows 402. The PV cell rows 402 are evenly spaced in parallel to form an array with a pitch b4.

The back surface of the cover plate 401 includes an array of trapezoidal grooves such as 403 with a pitch b4. Typically, the depth d4 of the trapezoidal groove is in a range of 0.5-50 mm. Each of the trapezoidal grooves has a pair of symmetrical planar sidewalls such as 409a and 409b. The reflective beam splitter strips, such as 405, are evenly spaced in parallel to form an array with a pitch b4. The PV cell rows such as 402, the trapezoidal grooves such as 403, the reflective beam splitters such as 405, and the TIR grooves such as 406 are in parallel to each other. Here, “trapezoidal groove” refers to a structure in which any cross sectional view on its longitudinal axis is a trapezoid with two parallel sides of different length and a pair of symmetrical unparallel sides of identical length.

Each reflective beam splitter of the reflective beam splitter array can be an optical diffuser, a grating, or an array of micro V grooves. The light impinging on a reflective beam splitter such as 405 is reflected upwardly into the sidewalls 407a or 407b or bottom surface 411 of the nearest TIR groove 406 and ultimately substantially backwards toward the active surface of the related PV cell rows 402. The geometry of the symmetrical sidewalls 407a and 407b or bottom surface 411 of the TIR groove 406 is such that the reflected light from the reflective beam splitters 405 is reflected to the active areas of the PV cell rows 402. Because of this geometrical design, relatively less PV cells are required for a same size PV panel. Thus, light energy is used more effectively and efficiently. By placing each reflective beam splitter of the reflective beam splitter array 405 in the top surface areas 410 of the related trapezoidal groove 403 of the beam splitter enhancement trapezoidal groove array, the width a4 of the PV cell row 402 is much less than the pitch b4 of PV cell array. The larger concentration M=(1+b/a) and low aspect ratio As=L/(a+b) can be achieved.

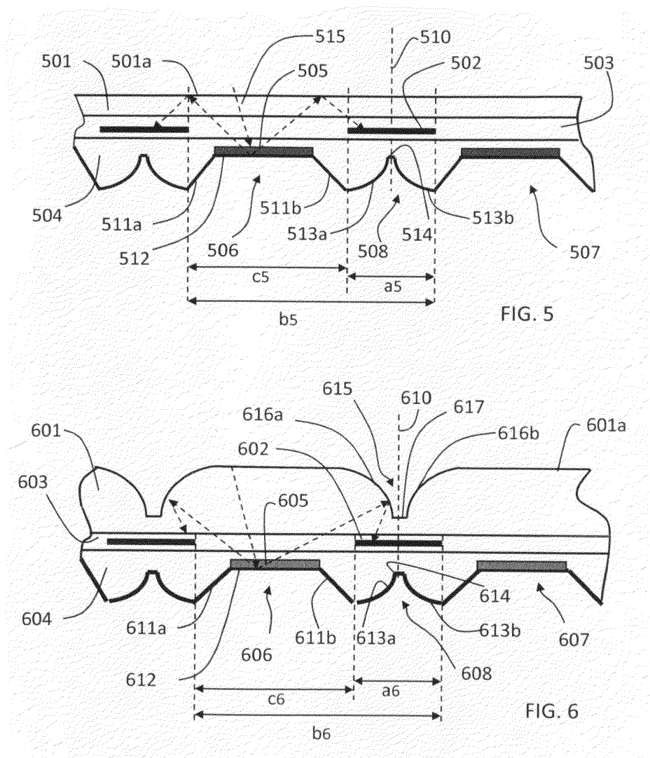

FIG. 5 is a schematic fragmentary diagram illustrating a cross sectional view of a flat plate concentrator PV panel according to another preferred embodiment of the present invention. The concentrator PV panel includes a cover plate 501 and a back plate 504 as a transmitting plate with an array of reflection grooves such as 508 and an array of trapezoidal reflection grooves such as 506 wherein the reflective beam splitter 505 are coupled on the top surface of the trapezoidal groove 506. An array of bifacial PV cell rows such as 502 is sandwiched by the cover plate 501 and back plate 504 through a transparent adhesive layer 503. The cover plate 501 is made of a light transparent optical medium, such as optical glass, with a flat front surface 501a. Both the front and back surfaces of bifacial PV cell row 502 are active with photovoltaic properties. The back plate 504 includes an array of trapezoidal grooves such as 506 which are evenly spaced in parallel and are located on the backside of the back plate 504, and an array of inverted reflection grooves such as 507 which are evenly spaced in parallel and are located on the backside of the back plate 504. The trapezoidal groove 506 includes a top plane 512 and a pair of symmetrical sidewalls 511a and 511b. The inverted reflection groove 508 includes a top plane 514 and a pair of symmetrical sidewalls 513a and 513b. The cover plate's “front surface” refers to the surface of the concentrator PV panel directly facing the light source such as sunlight. The back plate's “backside” refers to the opposite side of the front surface of the concentrator PV panel. Trapezoidal groove refers to a structure in which any cross section view at a right angle to its longitudinal axis is a trapezoid with two parallel sides of different length and a pair of symmetrical unparallel sides of identical length. The trapezoidal groove's “top plane” refers to the planar area where the trapezoid's narrow side resides. The “inverted reflection groove” refers to a structure in which any cross sectional view at a right angle to its longitudinal axis is an inverted V shape with a pair of symmetrical sides.

The back plate 504 includes an array of reflective beam splitters such as 505 which are evenly spaced in parallel and are coupled in the areas immediately above the top plane 512 of the trapezoidal groove 506. The array of PV cell rows such as 502 are evenly spaced in parallel and in the areas between two adjacent trapezoidal grooves, such as 506 and 507, and facing the inverted reflection groove 508 which is also between the trapezoidal grooves 506 and 507.

Each of the inverted reflection grooves 508 is located between two trapezoidal grooves 506 and 507, and has a pair of sidewalls 513a and 513b symmetrical to the middle line 510. The inverted reflection groove 508 is for optical length reduction. Its sidewalls 513a and 513b can be flat or curved surfaces having reflection properties. For a pair of symmetrical curved surfaces, the cross sectional view of a surface can be parabolic, elliptical, spherical, or a step curve. The upper planar surface 514 of the inverted reflection groove 508 and the PV cell row 502 have the same central line 510. The “upper planar surface” means the planar area facing the backside of the PV cell 502. The geometry of symmetrical sidewalls 513a and 513b of the inverted reflection groove 508 is such that the light impinging on the sidewalls 513a and 513b is substantially reflected to the active area on the back surface of the PV cell row 502. Here, “back surface” refers to the surface facing the inverted reflection groove 508.

In the preferred implementation, the width of the space between two adjacent PV cell rows is substantially same as the width of the wider side of the trapezoid 506, as marked “c5” in FIG. 5, and the width of the PV cell row 502 is substantially same as the width of the space between two adjacent trapezoidal grooves' bottom sides, as marked “a5” in FIG. 5.

Note that the reflective beam splitter 505 and the PV cell row 502 are located on different planes. The PV cell row 502, the trapezoid groove 506, the reflective beam splitter strip 505, and the inverted reflection groove 508 are all in parallel to each other.

The reflective beam splitter 505 can be an optical diffuser, a grating, or an array of micro V-shape grooves. As an example, the light 515 impinging on the reflective beam splitter 505 is substantially reflected upwardly into the inner surface of the front surface 501a of cover plate 501 and is ultimately substantially reflected back to the active areas of the PV cell 502. The geometry of symmetrical sidewalls 511a and 511b of the trapezoidal groove 506 is such that the light impinging on the sidewalls 511a and 511b is substantially reflected to the active areas on the back surface of the PV cell 502. Because of this geometrical design, the width a5 of the PV cell 502 is much less than the pitch b5 of PV cell array. Therefore, relatively less PV cells are required for a same size PV panel and light energy is used more effectively and efficiently.

FIG. 6 is a schematic fragmentary diagram illustrating a cross sectional view of a flat plate concentrator PV panel according to another preferred embodiment of the present invention. This embodiment is a combination of the embodiment illustrated in FIG. 4 and the embodiment illustrated in FIG. 5. The concentrator PV panel includes a cover plate 601, which is similar to the cover plate 401 in FIG. 4, and a back plate 604 as a transmitting plate wherein the reflective beam splitters such as 605 are coupled.

The cover plate 601 is made of a light transparent optical medium, such as optical glass, having an array of TIR grooves, such as 615, which are evenly spaced in parallel and are located above the bifacial PV cell rows, such as 602.

The TIR groove 615 is located directly against the PV cell row 602. In other words, the longitudinal axis of the TIR groove 615 is parallel to the longitudinal axis of the PV cell row 602, but the cross section of the TIR groove 615 and the cross section of the PV cell row 602 share a same central line 610 which is at a right angle to the longitudinal axis of the PV cell row 602. The two sidewalls 616a and 616b of the TIR groove 615, symmetrical to the central line 610, can be flat or curved surfaces. For a pair of symmetrical curved surfaces, the cross sectional view of a surface can be parabolic, elliptical, spherical, or a step curve. The geometrical properties of the sidewalls are designed according to such a calculation that each of the sidewalls has TIR properties to the reflected light from the reflective beam splitter 605 coupled in the back plate 604. In other words, the sidewalls 616a and 616b of the TIR groove 615 totally internally reflect substantially all the light from the reflective beam splitter 605 to the active areas on the front surface of the PV cell row 602.

The back plate 604 includes an array of trapezoidal grooves, such as 606 and 607, which are evenly spaced in parallel and are located on the backside of the back plate 604, and an array of inverted reflection grooves, such as 608, which are evenly spaced in parallel and are located on the backside of the back plate 604. The trapezoidal groove 606 includes a top plane 612 and a pair of symmetrical sidewalls 611a and 611b. The inverted reflection groove 608 includes a top plane 614 and a pair of symmetrical sidewalls 613a and 613b. The trapezoidal groves and the inverted reflection grooves are alternately arranged.

Incorporated in the back plate 604 is an array of planer reflective beam splitter strips, such as 605, which are evenly spaced in parallel and are coupled in the areas immediately above the top plane 612 of the trapezoid groove 606. The bifacial PV cell rows, such as 602, are evenly spaced in parallel and are sandwiched by the cover plate 601 and the back plate 604 by the transmission polymer 603.

Each of the inverted reflection grooves, such as 608, located between two adjacent trapezoidal grooves 606 and 607, has a upper planar surface 614 and a pair of symmetrical sidewalls 613a and 613b. The reflection groove 608 is for optical length reduction. Its sidewalls 613a and 613b can be flat or curved surfaces. For a pair of symmetrical curved surfaces, the cross sectional view of a surface can be parabolic, elliptical, spherical, or a step curve. The geometry of symmetrical sidewalls 613a and 613b of the inverted reflection groove 608 is such that the light impinging on the sidewalls 613a and 613b is substantially reflected to the back surface of the bifacial PV cell row 602. The “back surface” refers to the surface facing the inverted reflection groove 608. The upper planar surface 614 of the inverted reflection groove 608, the bottom planar surface 617 of the TIR groove 615, and the PV cell row 602 have the same central line 610. In other words, the inverted reflection groove 608, the TIR groove 615, and the PV cell row 602 are respectively symmetrical to the central line 610 at a right angle to their longitudinal direction.

In the preferred implementation, the width of the space between two adjacent PV cell rows, as marked “c6” in FIG. 6, is substantially same as the width of the wider side of the trapezoid 606, and the width of the PV cell row 602, as marked “a6” in FIG. 6, is substantially same as the width of the space between two adjacent trapezoidal grooves' bottom sides.

Note that the reflective beam splitters 605 and the PV cell rows 602 are located on different planes. The TIR grooves such as 615, the PV cell rows such as 602, the trapezoidal grooves such as 606, the reflective beam splitter strips such as 605, and the inverted reflection grooves such as 608 are all in parallel to each other horizontally.

The reflective beam splitter 605 can be an optical diffuser, a grating, or an array of micro V-shape grooves. The light impinging on the reflective beam splitter 605 is reflected upwardly into the inner surface of the front surface 601a of the cover plate 601 or the sidewalls 616a/616b of the TIR groove 615 and is reflected ultimately substantially backward to the active areas on the front surface of the PV cell 602. The geometry of symmetrical sidewalls 611a/611b of the trapezoidal groove 606 is such that the light impinging on the sidewalls 611a or 611b is reflected substantially to the active area on the back surface of the PV cell 602.

The sidewalls 616a/616b of the TIR groove 615, the sidewalls 611a/611b of the trapezoidal groove 606, and the sidewalls 613a/613b of the inverted reflection groove 608 can be flat or curves surfaces satisfying the maximal reflection or concentration of light to the active areas of the PV cells.

Because of the geometrical designs of the TIR grooves, the inverted reflection grooves and the trapezoidal grooves as described above, the width a6 of the PV cell 602 is much less than the pitch b6 of PV cell array, and much less PV cells are required for a same size PV panel. Thus, light energy is used more effectively and efficiently.

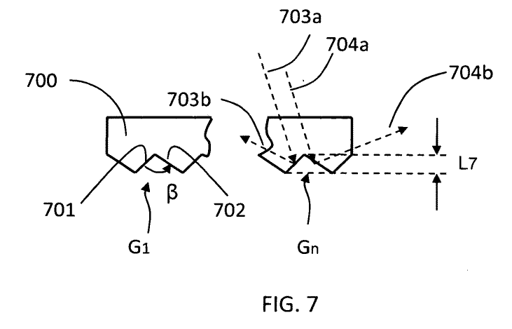

FIG. 7 is a schematic diagram illustrating a cross sectional view of a reflective beam splitter 700 which is used in the embodiments illustrated in FIGS. 2-6. The reflective beam splitter 700 has an array of micro V shape grooves G1-Gn located on the backside with a groove angle β (between the two sidewalls 701/702 of the micro V shape groove) depending on the refractive index of the optical transparent materials used for the reflective beam splitter and on the refractive index of the optical transparent materials used for the cover plate. As an example, the light 703a is changed to light 703b; the light 704a is changed to light 704b. In this manner, the parallel beam 703a/704a is split into unparallel beams 703b and 704b. In the typical embodiments of this invention, the angle β ranges in 100˜140 degrees. The depth L7 of the micro V groove ranges in 0.01 to 50 mm.

In the above described preferred embodiments, the beam splitter can be formed on the tope of the trapezoidal grooves directly or formed as thin film and laminated to the tope plane of the trapezoidal grooves. The non-transparent sidewalls of the trapezoidal groove and the reflective beam splitters can be coated with a multilayer dielectric coating mirror or a humidity-protected metal mirror such as, but not limited to, Silicon Dioxide coated metal foil or metal coating, metal coated polyethylene terephthalate (PET) film and metal coated polyvinyl fluoride (PVF) film. The adhesive used for fixing the PV cell array between the light transparent cover plate and the transmitting plate includes, but not limited to optical epoxies, ethylene vinyl acetate (EVA) and polyurethanes. The PV cell array includes a plurality of rows of PV cells with rectangular active area. The PV cell can be, but not limited to, monolithic PV cell and PV cell linear array electrically coupled to each other in series or in parallel. The concentrator PV panel according to the present invention can be incorporated in a square, rectangular, or any other shape of frame. Because of the innovative structures of the PV panels according to the present invention, sunlight tracking systems are not required for normal operation.

While one or more embodiments of the present invention have been illustrated in detail, the skilled artisan will appreciate that modifications and adoptions to those embodiments may be made without departing from the scope and spirit of the present invention as set forth in the following claims.

1. A flat plate concentrator photovoltaic (PV) panel, comprising:
a transparent cover plate having an array of a total internal reflection (TIR) grooves;
a water proof back plate;
an array of rows of PV cells;
an array of strips of beam splitters being alternate with said rows of PV cells;
wherein said rows of PV cells and said strips of beam splitters are sandwiched in a transparent and insulative adhesive by said cover plate and said water proof back plate; and
wherein each of said TIR grooves is located above one of said rows of PV cells and has total reflection properties to reflect light from said beam splitters to said PV cells.

2. The flat plate concentrator PV panel of claim 1, wherein said array of rows of PV cells and said array of strips of beam splitters have a same pitch in a range of 1-100 mm.

3. The flat plate concentrator PV panel of claim 1, wherein width of each of said rows of PV cells is in a range of 1-50 mm.

4. The flat plate concentrator PV panel of claim 1, wherein each of said TIR grooves has a flat bottom surface and a pair of sidewalls symmetrical to a central line at a right angle to a longitudinal direction of said flat bottom surface, both said flat bottom surface and said symmetrical sidewalls having TIR properties to reflect light from said beam splitters substantially to said PV cells.

5. The flat plate concentrator PV panel of claim 4, wherein each of said TIR grooves has a depth in a range of 0.5-10 mm.

6. The flat plate concentrator PV panel of claim 4, wherein said pair of symmetrical sidewalls is a pair of symmetrical curved surfaces.

7. The flat plate concentrator PV panel of claim 1, wherein said beam splitters can be any of:
diffusers;
gratings; and
micro V grooves.

8. A flat plate concentrator PV panel, comprising:
a transparent cover plate with an anti-reflection front surface and a grooved backside, said grooved backside having an array of trapezoidal grooves, each of said trapezoidal grooves having a flat top surface and a pair of sidewalls symmetrical to a central line at a right angle to a longitudinal direction of said trapezoidal groove;
an array of rows of PV cells coupled in said backside along said trapezoidal grooves' longitudinal direction, each of which being located above a lower bottom area between two adjacent trapezoidal grooves;
an array of strips of reflection beam splitters, each of which being located above a trapezoidal groove's flat top surface, said beam splitters being alternate with said rows of PV cells;
a water proof back plate;
wherein said array of rows of PV cells and said array of strips of reflection beam splitters are sandwiched in a transparent and insulative adhesive by said cover plate and said back plate;
wherein said symmetrical sidewalls of said trapezoidal grooves are mirror coated and have total reflection properties to reflect light impinging thereon substantially to said cover plate's front surface; and
wherein said cover plate's front surface has TIR properties to reflect light from said beam splitters and said symmetrical sidewalls substantially to said PV cells.

9. The flat plate concentrator PV panel of claim 8, wherein each of said trapezoidal grooves has a groove angle between said sidewalls in a range of 90-160 degrees and a depth in a range of 0.5-50 mm.

10. The flat plate concentrator PV panel of claim 8, wherein said pair of symmetrical sidewalls of said trapezoidal grooves is a pair of symmetrical flat surfaces.

11. The flat plate concentrator PV panel of claim 8, wherein said anti-reflection front surface is any of:
a coated flat surface; and
a grooved surface having a plurality of evenly spaced V shape grooves, each of which having a pair of symmetrical sidewalls.

12. The flat plate concentrator PV panel of claim 11, wherein said pair of symmetrical sidewalls of said V shape grooves is a pair of symmetrical flat surfaces.

13. The flat plate concentrator PV panel of claim 8, wherein said beam splitters can be any of:
diffusers;
gratings; and
micro V shape grooves.

14. A flat plate concentrator PV panel, comprising:
a transparent cover plate with an anti-reflection front surface;
a transparent medium with a flat front surface and a flat back surface wherein a plurality of evenly spaced rows of bifacial PV cells are coupled, said transparent medium's flat front surface being coupled to said cover plate's back surface;
a transparent water proofed back plate having a grooved backside, said water proofed back plate's front surface being coupled to said transparent medium's back surface;
an array of trapezoidal grooves on said water proofed back plate's backside, each of which having a flat top surface and a pair of sidewalls symmetrical to said flat top surface's central line at a right angle to said trapezoidal grooves' longitudinal direction and being parallel to said rows of bifacial PV cells;
an array of strips of beam splitters, each of which being coupled in and located above a trapezoidal groove's upper planar area, said strips of beam splitters being parallel to and alternate with said rows of bifacial PV cells;
an array of inverted reflection grooves on said water proofed back plate's backside, each of which having a flat top surface and a pair of sidewalls symmetrical to a central line at a right angle to said inverted reflection grooves' longitudinal direction and being parallel to and under a row of bifacial PV cells, and said inverted reflection grooves being alternate with and parallel to said trapezoidal grooves;
wherein said cover plate's front surface has TIR properties to reflect light from said beam splitters substantially to said bifacial PV cells; and
wherein said inverted reflection grooves' symmetrical sidewalls have total reflection properties to reflect light impinging thereon substantially to said bifacial PV cells.

15. The flat plate concentrator PV panel of claim 14, wherein said pair of symmetrical sidewalls of said trapezoidal grooves is a pair of symmetrical flat surfaces.

16. The flat plate concentrator PV panel of claim 14, wherein said pair of symmetrical sidewalls of said inverted reflection grooves is any of:
a pair of symmetrical flat surfaces; and
a pair of symmetrical curved surfaces.

17. The flat plate concentrator PV panel of claim 14, wherein said cover plate's anti-reflection front surface is any of:
an anti-reflection coated flat surface; and
a grooved surface having a plurality of evenly spaced V shape grooves.

18. The flat plate concentrator PV panel of claim 17, wherein said pair of symmetrical sidewalls of said V shape grooves is a pair of symmetrical flat surfaces.

19. The flat plate concentrator PV panel of claim 14, wherein said beam splitters can be any of:
diffusers;
gratings; and
micro V shape grooves.

20. The flat plate concentrator PV panel of claim 19, wherein each of said micro V shape grooves has a groove angle in a range of 100-140 degrees and a groove depth in a range of 0.01-50 mm.
